(19) United States
(12) Patent Application Publication
(10) Pub. No.: US 2006/0182973 A1
(43) Pub. Date: Aug. 17, 2006

(54) Resin composition and ceramic/polymer composite for embedded capacitors having excellent TCC property

(75) Inventors: Seung Eun Lee, Sungnam (KR); Yul Kyo Chung, Yongin (KR); Min Ji Ko, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/352,233

(22) Filed: Feb. 13, 2006

(30) Foreign Application Priority Data
Feb. 15, 2005 (KR) 10-2005-0012482

(51) Int. Cl. B32B 27/38; C08L 63/00; H01L 21/56

(52) U.S. Cl. 428/413; 523/400; 523/440; 523/457; 525/524

(57) ABSTRACT

Disclosed herein is a resin composition and ceramic/polymer composite for dielectric layers of embedded capacitors having a high dielectric constant, a dielectric layer of a capacitor manufactured therefrom, and a printed circuit board including the dielectric layer. In addition, a method of increasing temperature stability and a dielectric constant of the ceramic/polymer composite for dielectric layers of embedded capacitors is also provided. The resin composition for embedded capacitors includes 5-30 wt % of at least one resin selected from the group consisting of bisphenol-A epoxy resins, bisphenol-F epoxy resins and combinations thereof, 60-85 wt % of at least one resin selected from the group consisting of novolac-type epoxy resins, polyimides, cyanate esters and combinations thereof, and 10-30 wt % of a multi-functional epoxy resin, and the ceramic/polymer composite includes such a resin composition. Further, the dielectric layer of a capacitor formed of the ceramic/polymer composite of the current invention is provided along with the printed circuit board including the dielectric layer.

### BACKGROUND OF THE INVENTION

1. Field of the Invention

The present invention relates, generally, to a dielectric material for embedded capacitors having a high dielectric constant, and, more particularly, to a ceramic/polymer composite having a high dielectric constant and high temperature stability.

2. Description of the Related Art

Recently, while a multilayered circuit board has been developed to be miniaturized and have a high frequency, passive devices, which have been generally mounted on a printed circuit board (PCB), impede the miniaturization of products. In particular, semiconductor devices have increasingly trended towards being embedded and the number of input/output terminals has increased, and thus, it is difficult to assure the space required to dispose many passive devices including capacitors around active integrated circuit chips.

Further, with the aim of supplying stable power to an input terminal, a decoupling capacitor is used. As such, a high frequency decoupling capacitor should be disposed nearest to the input terminal, to reduce the high frequency induced inductance.

To optimally dispose the capacitor around the active integrated circuit chips to correspond to the miniaturization and high frequency requirements of electronic devices, methods of embedding passive devices, such as the capacitor, directly below the integrated circuit chip have been proposed. Accordingly, a multilayered ceramic capacitor (MLCC) having low equivalent series inductance (low ESL) has been developed.

Moreover, to overcome the problems of high frequency induced inductance and realize miniaturization, embedded capacitors have been devised. The embedded capacitor is manufactured by forming one layer in a PCB below the active integrated circuit chip as a dielectric layer. The embedded capacitor is disposed nearest to the input terminal of the active integrated circuit chip, and thus, the length of the wire connected to the capacitor is minimized, thereby effectively reducing the high frequency induced inductance.

It is known that a dielectric material for capacitors used to realize the embedded capacitor includes, for example, a glass fiber reinforced epoxy resin called the FR4, which is used as a conventional PCB member. For necessary capacitance, a filler formed of ferroelectric ceramic powder having a high dielectric constant is dispersed in a polymer to obtain a composite, which is then used as a dielectric material for embedded composites. For example, as a highly dielectric composite for embedded capacitors, a composite formed by dispersing a BaTiO₃ filler which is a ferroelectric ceramic material in an epoxy resin is used. In this way, in the case where the polymer-ferroelectric ceramic composite is used as a dielectric material for embedded capacitors, the volume ratio of the ferroelectric ceramic filler to the polymer should increase or the dielectric constant of the polymer should increase, so as to increase the dielectric constant.

However, when the dielectric constant is increased by increasing the volume ratio of the ferroelectric ceramic filler such as BaTiO₃, it may drastically vary at a predetermined high temperature due to temperature properties of the ferroelectric ceramic filler. For example, in the composite obtained by dispersing a 45 vol % BaTiO₃ filler in the epoxy resin, the dielectric constant drastically increases at about 125° C., and therefore, the temperature stability to capacitance of the capacitor is extremely aggravated. This is because BaTiO₃ dispersed in a large vol % in the epoxy resin is phase transferred from a tetragonal phase to a cubic phase at about 125° C. while the temperature increases.

Likewise, the method of increasing the dielectric constant of the polymer may be used to obtain a ceramic/polymer composite having a high dielectric constant. To increase the dielectric constant of the polymer, methods of increasing the polarity of a polymer chain have been proposed, which include adding a metal ion organic catalyst to the polymer. As for the material manufactured using the above method, while the polarity of the polymer increases, the dielectric constant of the polymer itself increases, ultimately resulting in an increased dielectric constant. However, the temperature stability is drastically deteriorated at a predetermined high temperature.

For a high dielectric constant of a composite, thorough research into increasing the dielectric constant of epoxy has been conducted. In this regard, U.S. Pat. No. 6,544,651 discloses a method of increasing a dielectric constant of an epoxy resin by adding a metal organic catalyst to the epoxy resin, thus increasing the polarity of the epoxy resin. However, when increasing the dielectric constant of the epoxy resin, the above patent has not considered the temperature stability of capacitance (TCC) to be an important property of embedded capacitors. In the actual test (FIG. 2), it appears that the temperature stability is further deteriorated even if the dielectric constant is increased. Thus, the epoxy resin having a high dielectric constant with an added metal organic catalyst should exhibit stable TCC property in order to be used as a matrix material for embedded capacitors.

In this way, in the case where the ceramic/polymer composite containing a ferroelectric ceramic material serves as a dielectric material for capacitors, it is very difficult to achieve excellent temperature stability at a high temperature while assuring a high dielectric constant.

### SUMMARY OF THE INVENTION

Accordingly, the present invention has been made keeping in mind the above problems occurring in the related art, and an object of the present invention is to provide a dielectric material for embedded capacitors having a high dielectric constant, in which a polymer material having excellent temperature stability is used and a curie temperature (Tc) of ferroelectric powder is changed, thereby increasing the dielectric constant of the dielectric material and solving the problems of temperature stability deteriorating at a high temperature.

In order to accomplish the above object, according to a first aspect of the present invention, a resin composition for embedded capacitors is provided, which comprises 5-30 wt % of at least one resin selected from the group consisting of bisphenol-A epoxy resins, bisphenol-F epoxy resins and combinations thereof, 60-85 wt % of at least one resin selected from the group consisting of novolac-type epoxy resins, polyimides, cyanate esters and combinations thereof, and 10-30 wt % of a multi-functional epoxy resin.

According to a second aspect of the present invention, a ceramic/polymer composite for embedded capacitors is provided, which comprises 50-70 vol % of a resin mixture including 5-30 wt % of at least one resin selected from the group consisting of bisphenol-A epoxy resins, bisphenol-F epoxy resins and combinations thereof, 60-85 wt % of at least one resin selected from the group consisting of novolac-type epoxy resins, polyimides, cyanate esters and combinations thereof, and 10-30 wt % of a multi-functional epoxy resin, and 30-50 vol % of a ceramic filler.

According to a third aspect of the present invention, a dielectric layer of a capacitor is provided, which is formed of the ceramic/polymer composite including the resin mixture and the ceramic filler.

According to a fourth aspect of the present invention, a PCB is provided, which comprises the dielectric layer of a capacitor.

According to a fifth aspect of the present invention, a method of increasing the dielectric constant of a ceramic filler for embedded capacitors is provided, which comprises heat treating ferroelectric powder at 800 to 1300° C., and pulverizing the heat treated powder to a size of 0.01 to 10 μm, to increase the curie temperature of the ceramic filler.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a graph showing TCC properties of ceramic/polymer composites manufactured in Comparative Examples 1 and 2 according to a conventional technique;

FIG. 2 is a graph showing TCC properties of an epoxy resin in which a dielectric constant is not increased and an epoxy resin having a dielectric constant increased by using an organic catalyst in Comparative Examples 3 and 4 according to a conventional technique;

FIG. 3 is a graph showing TCC properties varying with the kinds of epoxy resin in Example 1 according to the present invention and Comparative Examples 5 to 7 according to a conventional technique;

FIG. 4 is a graph showing TCC properties of polymers, each of which has different polarity and is mixed with the same filler, in Example 2 according to the present invention and Comparative Example 8 according to a conventional technique;

FIG. 5 is a graph showing TCC properties varying with Tc of ferroelectric materials in Examples 3 to 5 according to the present invnetion; and

FIG. 6 is a graph showing TCC properties varying with Tc when the same resin and the same filler are used in Example 2 according to the present invention and Comparative Example 9 according to a conventional technique.

### DESCRIPTION OF THE PREFERRED EMBODIMENTS

In the present invention, a ceramic/polymer composite for dielectric layers of embedded capacitors, which includes a resin and a ceramic filler, has high dielectric properties and excellent temperature stability.

According to a first embodiment of the present invention, a resin composition for embedded capacitors is provided, which includes a resin mixture composed of two or more polymers to exhibit excellent temperature stability.

As the polymer used for the resin composition, a polymer having relatively low polarity is preferably used. The polymer having relative polarity relies on electronic bond and dipolar polarization models. The polar polymer has permanent dipoles, and thus, dipolar polarization of two polarizations greatly affects the TCC property. The permanent dipoles in the polymer are difficult to arrange in a predetermined direction even though an electrical field is applied at a low temperature, due to a long polymer chain, unlike in a ceramic.

However, when the temperature gradually increases and reaches a predetermined temperature, that is, Ts (softening point), these dipoles are more freely moved and easily arranged in a direction of an electrical field, thereby increasing a dielectric constant. This phenomenon is easily manifested in a polymer having higher polarity because the dipoles may be relatively easily arranged as the polarity of the polymer increases. In addition, the above phenomenon is more apparent in a thermoplastic resin having relatively freely arranged dipoles than in a thermosetting resin in which the dipoles move little due to a strong crosslinked bond. That is, if the arrangement of dipoles easily occurs in the polymer chain, the TCC property of the polymer is deteriorated. In the case where the polymer has low Ts and Tc, the TCC property becomes inferior even at a temperature lower than the above temperatures. Hence, to improve the temperature stability, it is preferable that a polymer having low polarity be used.

The polymer used in the present invention is exemplified by, but is not limited to, at least one resin selected from the group consisting of bisphenol-A epoxy resins, bisphenol-F epoxy resins and combinations thereof, at least one resin selected from the group consisting of novolac-type epoxy resins, polyimides, cyanate esters and combinations thereof, and a multi-functional epoxy resin.

In order to alleviate drastic aggravation of temperature stability caused by using ferroelectric powder as a dielectric layer material for embedded capacitors having a high dielectric constant, use of a polymer having relatively low polarity is required. In addition, the polymer has high Ts and Tg and high crosslinking density, as well as low polarity, as controllable properties for overcoming the aggravation of the temperature stability.

Hence, of the polymers, a bisphenol-A epoxy resin, a brominated epoxy resin and a bisphenol-A novolac epoxy resin, each of which has relatively low polarity, high Ts and Tg and high crosslinking density, are preferably mixed for use.

In the resin composition for embedded capacitors, at least one resin selected from the group consisting of bisphenol-A epoxy resins, bisphenol-F epoxy resins, and combinations thereof is contained in an amount of 5-30 wt %, and at least one resin selected from the group consisting of novolac-type epoxy resins, polyimides, cyanate esters, and combinations thereof is contained in an amount of 60-85 wt %. Additionally, a multi-functional epoxy resin is contained in an amount of 10-30 wt %.

As such, if a resin such as bisphenol-A epoxy resin is used in an amount less than 5 wt %, the cured resin may break loose. Meanwhile, if the amount of the above resin exceeds 30 wt %, Tg does not reach the temperature required for a dielectric layer material. Further, if the resin such as novolac-type epoxy is used in an amount less than 60 wt %, Tg also decreases. On the other hand, when the above resin is used in an amount exceeding 85 wt %, peel strength decreases, thus causing problems in manufacturing reliable PCBs. Furthermore, use of the multi-functional epoxy resin in an amount less than 10 wt % results in low fire resistance, whereas use of the multi-functional epoxy resin exceeding 30 wt % results in undesirably weakened peel strength.

According to a second embodiment of the present invention, a ceramic/polymer composite for embedded capacitors is provided, which includes the resin mixture and a ceramic filler having a high dielectric constant to exhibit excellent temperature stability and a high dielectric constant.

To increase the dielectric constant of the composite, the ferroelectric powder must be used. However, when the ferroelectric powder reaches a temperature near Tc, phase transfer from a tetragonal phase to a cubic phase occurs. Due to the phase transfer phenomenon, the lattice of the above material undergoes stress, and thus, the dielectric constant drastically varies. Since capacitance is the function of dielectric constant, the temperature stability of capacitance is deteriorated.

To solve the above problems, U.S. Pat. No. 6,608,762 discloses a method of using nano-sized BT particles. Since the nano-sized BT particles have a cubic phase at room temperature, the phase transfer does not occur at Tc. Accordingly, the TCC property may be improved. However, the composite thus manufactured has a low dielectric constant of 30 or less even though it fulfills TCC property for an X7R. That is, use of the ferroelectric powder having a tetragonal phase is inevitable to increase the dielectric constant.

In the present invention, to manufacture a composite having a high dielectric constant while maintaining a tetragonal phase, a method of changing the Tc of ferroelectric material is employed. That is, the ceramic filler is pulverized, whereby the ferroelectric powder is not phase transferred even at a temperature near Tc, thus preventing the drastic variation of dielectric constant. In addition, even if the filler is pulverized by heat treatment, it may maintain the tetragonal phase. Hence, the ceramic/polymer composite manifests a satisfactory TCC property with a high dielectric constant.

The ceramic filler is used in an amount of 30 to 50 vol % based on the total volume of the ceramic/polymer composite. When the ceramic filler is used in an amount less than 30 vol %, capacitance undesirably decreases. Meanwhile, if the amount of ceramic filler exceeds 50 vol %, less epoxy resin is used, and thus, the strength of adhesion to the metal foil is undesirably weakened.

The ceramic filler includes, for example, but is not limited to, ferroelectric insulators, such as BaTiO₃, PbTiO₃, PMT-PT, SrTiO₃, CaTiO₃, MgTiO₃, or combinations thereof. Also, a ceramic filler having a particle size generally used in the art may be applied to the present invention.

The additive is selected from the group consisting of 2⁺, 3⁺ and 5⁺ oxides of Mn, Mg, Sr, Ca, Y and Nb, oxides of lanthanide elements including Ce, Dy, Ho, Yb and Nd, and combinations thereof.

The additive is used in an amount of 0.01-5 mol %, preferably, 1-2 mol %, based on 1 mol of the ferroelectric material. If the amount of the additive is less than 0.01 mol %, the dielectric constant is insignificantly increased. Meanwhile, if the above amount exceeds 5 mol %, the dielectric constant is undesirably reduced.

The ferroelectric material mixed with the additive is heat treated at 800-1300° C., preferably 1000-1300° C., for 0.5 to 2 hr in an oxidation atmosphere, a reduction atmosphere or a vacuum atmosphere.

If the heat treatment is performed at a temperature lower than 800° C. or for a time shorter than 0.5 hr, the amount of the additive is insufficient to be bonded to the ceramic filler, and thus, the dielectric constant is insignificantly increased. In contrast, if the heat treatment is performed at a temperature higher than 1300° C. or for a time longer than 2 hr, excessive growth of particles and thickened insulating layer result. Hence, the dielectric constant undesirably decreases.

The heat treatment may be carried out in a commonly used manner as an oxidation atmosphere, a reduction atmosphere or a vacuum atmosphere.

The ceramic filler, which has been mixed with the additive and heat treated, is exemplified by, but is not limited to, BaCaTiO₃, which is formed by mixing BaTiO₃ powder with Ca and then heat treating the powder mixed with Ca. The exemplified ceramic filler is advantageous because it has a high dielectric constant, an unchanged tetragonal phase, and a high Tc. The ceramic filler thus obtained has a dielectric constant of 40 or more at room temperature in a range of 1 kHz, and Tc of 125° C. or more. Therefore, even in a high temperature process upon manufacturing the PCB, phase transfer from the tetragonal phase to the cubic phase due to the increase of Tc does not occur. In addition, the drastic variation of the dielectric constant, attributable to the phase transfer, does not occur, leading to stable TCC property.

The filler heat treated along with the additive is pulverized to an average particle size of 0.01 to 10 μm. If the particle size is smaller than 0.01 μm, it is difficult to uniformly disperse the pulverized particles. Meanwhile, if the particle size exceeds 10 μm, formability decreases upon manufacturing the capacitor, and a cavity may be undesirably formed.

In addition, the ceramic/polymer composite may further include a curing agent, a curing accelerator, a dispersing agent and/or a defoaming agent. The kinds and amounts of such components may be appropriately chosen by those skilled in the art.

The curing agent includes, for example, phenols such as bisphenol-A novolac resins, amines such as dicyandiamides, dicyanguanidines, diaminodiphenylmethanes or diaminodiphenyl sulfones, acid anhydrides such as trimellitic anhydrides or benzophenone tetracarboxylic anhydrides, or combinations thereof, as generally known materials. The curing accelerator includes materials known generally in the art, such as 2-methylimidazole.

According to a third embodiment of the present invention, a dielectric layer of an embedded capacitor manufactured using the ceramic/polymer composite for embedded capacitors is provided, in which the ceramic/polymer composite includes a resin mixture comprising three kinds of polymer and a ceramic filler formed by mixing a ceramic filler having a high dielectric constant with an additive, and heat treating and pulverizing it. Therefore, the dielectric layer has a high dielectric constant, and excellent TCC property that provides a temperature-stable X7R.

According to a fourth embodiment of the present invention, a PCB fabricated using the dielectric layer of an embedded capacitor is provided, in which the dielectric layer is formed of a ceramic/polymer composite that includes a resin mixture of two or more polymers and a ceramic filler that is heat treated and then pulverized. As such, the PCB has a high dielectric constant and excellent TCC property that provides a temperature-stable X7R.

According to a fifth embodiment of the present invention, a method of mixing at least one resin selected from the group consisting of bisphenol-A epoxy resins, bisphenol-F epoxy resins and combinations thereof, at least one resin selected from the group consisting of novolac-type epoxy resins, polyimides, cyanate esters and combinations thereof, and a multi-functional epoxy resin is provided, thereby improving the temperature stability of the dielectric layer material for embedded capacitors.

According to a sixth embodiment of the present invention, a method of increasing the dielectric constant of a ceramic filler for embedded capacitors is provided, which includes mixing ferroelectric powder with an additive to obtain a mixture, which is then heat treated at 800 to 1300° C. and pulverized to a size ranging from 0.01 to 10 μm.

A better understanding of the present invention may be obtained in light of the following Examples and Comparative Examples which are set forth to illustrate, but are not to be construed to limit the present invention.

### EXAMPLE 1

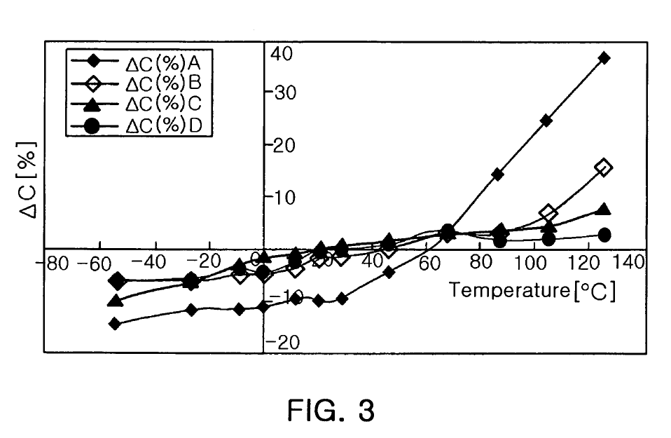

A dielectric layer for capacitors was manufactured using only a polymer. An 80 wt % resin mixture composed of a bisphenol-A novolac epoxy resin (EEW=210-240), a brominated bisphenol-A epoxy resin (EEW=380-420), and a bisphenol-A epoxy resin (EEW=184-190) was dissolved in 2-methoxyethanol. To the reaction solution, 0.8 eq bisphenol-A novolac resin and 0.1 wt % 2MI (2-methylimidazole) were further added as a curing agent and a curing accelerator, respectively, and the obtained solution was mixed at 50° C. The resultant mixture was cast on a Cu foil and then semi-cured to a B-stage for 2.5 min in an oven at 170° C., to obtain a resin coated copper foil (RCC). Subsequently, two RCCs were laminated at 200° C. to form a copper-clad laminate (CCL), which was then taped and etched using an aqueous nitric acid solution, forming electrodes. Then, the TCC property was measured. The measured results are shown in FIG. 3 (ΔC(%) D).

### EXAMPLE 2

To manufacture a ceramic/polymer composite, a ceramic filler having a particle size of 0.2 μm by heat treating BaCaTiO₃ (0.2 μm) at 1000° C. for 2 hr and pulverizing it for 2 hr, and the same polymer as in Example 1 were used. As such, the ratio of ceramic filler to polymer was 80 wt % (45 vol %) to 20 wt % (55 vol %).

Such a composite was manufactured according to the following procedures.

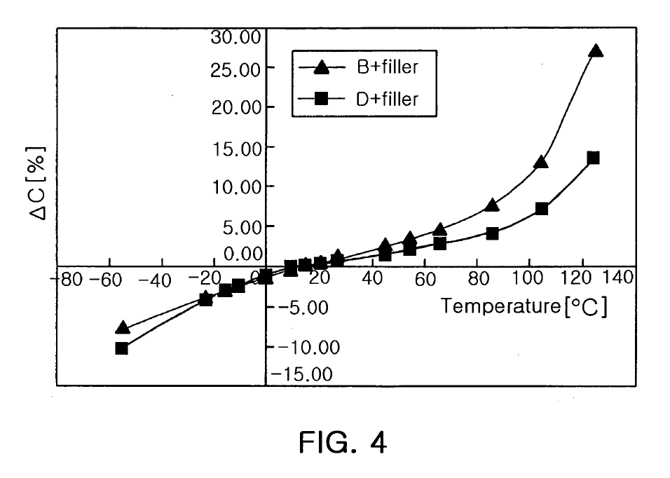

To an 80 wt % resin mixture dissolved in methylethylketone, 0.8 eq bisphenol-A novolac resin and 0.1 wt % 2MI were further added as a curing agent and a curing accelerator, respectively, and the obtained solution was mixed at 50° C. Thereafter, the resultant mixture was mixed with a dispersing agent, a defoaming agent, and BaCaTiO₃ amounting to 45 vol %, cast on a Cu foil and then semi-cured to a B-stage for 2.5 min in an oven at 170° C., to obtain an RCC. Two RCCs were laminated at 200° C. to form a CCL, which was then taped and etched using an aqueous nitric acid solution, forming electrodes. Subsequently, the TCC property was measured. The measured results are shown in FIGS. 4 (D+filler) and 6 (Tc=129.3° C.)

### EXAMPLE 3

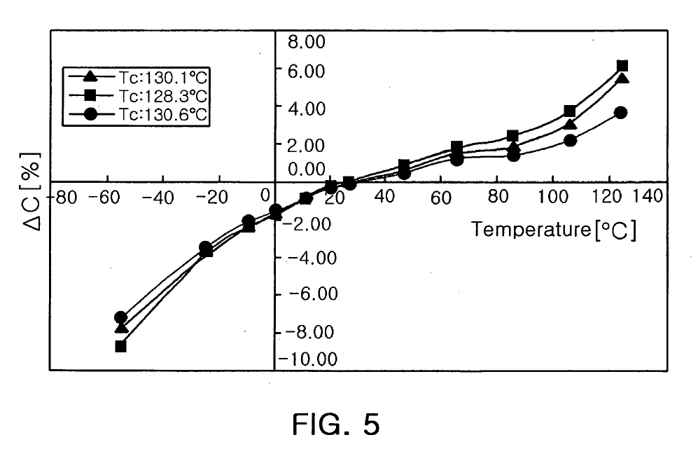

A ceramic/polymer composite was manufactured in the same manner as in Example 2. As such, BaTiO₃ (0.3 μm) was used as a ceramic filler, and an epoxy resin, a curing agent, and a curing accelerator were used in the same composition as in Example 1. The TCC property is depicted in FIG. 5 (Tc: 128.3° C.)

### EXAMPLE 4

A ceramic/polymer composite was manufactured in the same manner as in Example 2. As such, BaTiO₃ (0.5 μm) was used as a ceramic filler, and an epoxy resin, a curing agent, and a curing accelerator were used in the same composition as in Example 1. The TCC property is depicted in FIG. 5 (Tc: 130.1° C.).

### EXAMPLE 5

A ceramic/polymer composite was manufactured in the same manner as in Example 2. As such, BaTiO₃ (0.7 μm) was used as a ceramic filler, and an epoxy resin, a curing agent, and a curing accelerator were used in the same composition as in Example 1. The TCC property is depicted in FIG. 5 (Tc: 130.6° C.).

### COMPARATIVE EXAMPLE 1

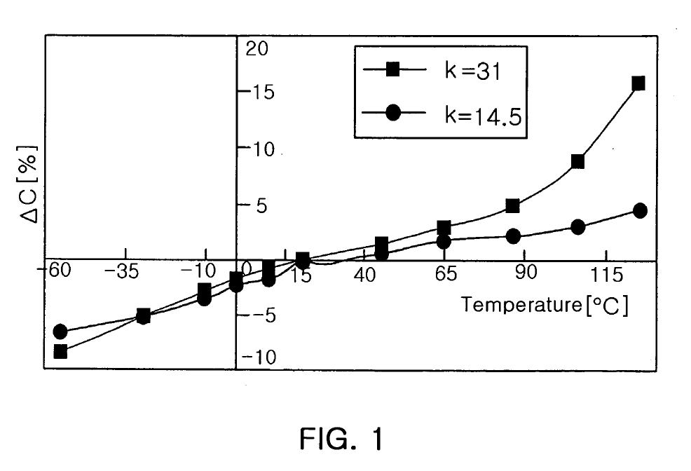

A ceramic/polymer composite was manufactured in the same manner as in Example 2. As such, a ceramic filler having a particle size of 0.2 μm by heat treating BaCaTiO₃ (0.25 μm) at 1100° C. for 2 hr and then pulverizing it for 12 hr was used, and a bisphenol-A novolac epoxy resin was used as a polymer, and DICY (dicyandiamide) as a curing agent was used in an amount of 2.5 wt % based on the weight of epoxy. The resultant dielectric constant is 31 at 1 kHz, and the TCC property is depicted in FIG. 1 (k=31).

### COMPARATIVE EXAMPLE 2

A ceramic/polymer composite was manufactured in the same manner as in Comparative Example 1, with the exception that BaTiO₃ (0.5 μm) was used as a ceramic filler. As such, the resultant dielectric constant is 14.5, and the TCC property is depicted in FIG. 1 (k=14.5).

### COMPARATIVE EXAMPLE 3

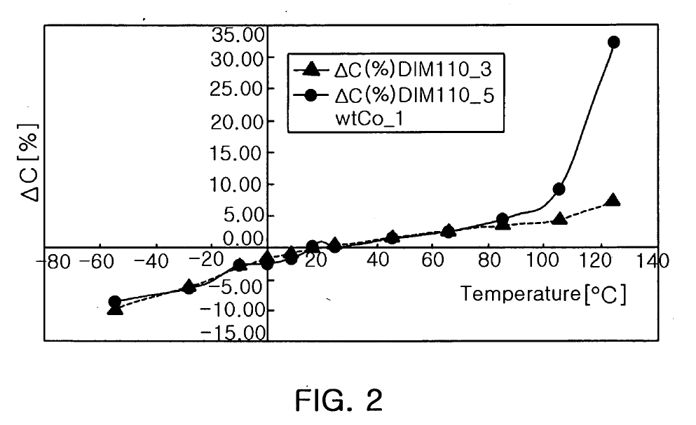

A dielectric layer was manufactured using only a polymer in the same manner as in Example 1, with the exception that as an epoxy resin, a brominated bisphenol-A epoxy resin (EEW 440-460) that was a FR-4 applied epoxy was used, and DICY as a curing agent was used in an amount of 2.9 wt % based on the weight of epoxy, and a ceramic filler was not used. The TCC property is depicted in FIG. 2 (DIM-110_{—}3).

### COMPARATIVE EXAMPLE 4

A dielectric layer was manufactured in the same manner as in Comparative Example 3, with the exception that cobalt (III) acetylacetonate was further used in an amount of 5 wt % based on the weight of epoxy. The TCC property is depicted in FIG. 2 (DIM-110_{—}5wtCo_{—}1).

### COMPARATIVE EXAMPLE 5

PMMA (poly(methyl methacrylate)) powder as a polymer was cured at 180° C. under pressure of 300 bar for 30 min using a mounting press (SIMPLIMET 1000). Then, to form electrodes, a copper foil cut to a predetermined size was attached to each of both surfaces of the cured polymer, which was then compressed at 150° C. under pressure of 300 bar for 5 min. The TCC property is depicted in FIG. 3 (ΔC (%) A).

### COMPARATIVE EXAMPLE 6

A ceramic/polymer composite was manufactured in the same manner as in Example 2. As such, a bisphenol-A novolac epoxy resin (EEW=270-310) as an epoxy resin, 2.5 wt % DICY as a curing agent, and 0.1 wt % 2MI as a curing accelerator were used. The TCC property is depicted in FIG. 3 (ΔC (%) B).

### COMPARATIVE EXAMPLE 7

A ceramic/polymer composite was manufactured in the same manner as in Example 2. As such, a brominated bisphenol-A epoxy resin (EEW=350-370) as an epoxy resin, 2.9 wt % DICY as a curing agent, and 0.1 wt % 2MI as a curing accelerator were used. The TCC property is depicted in FIG. 3 (ΔC (%) C).

### COMPARATIVE EXAMPLE 8

A ceramic/polymer composite was manufactured in the same manner as in Example 2. As such, an epoxy resin, a curing agent, and a curing accelerator were used in the same composition as in Comparative Example 6. The TCC property is depicted in FIG. 4 (B+filler).

### COMPARATIVE EXAMPLE 9

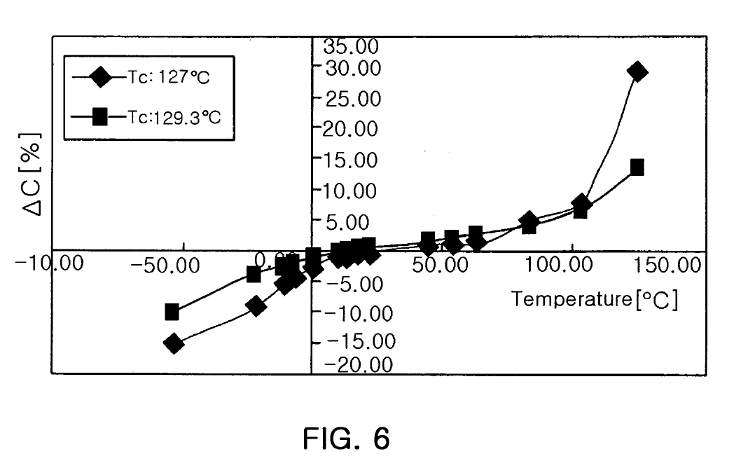

A ceramic/polymer composite was manufactured in the same manner as in Example 2. As such, a ceramic filler having a particle size of 0.2 μm by heat treating BaCaTiO₃ (0.2 μm) at 1100° C. for 2 hr and pulverizing it for 2 hr was used, and an epoxy resin, a curing agent, and a curing accelerator were used in the same composition as in Example 1. The TCC property is depicted in FIG. 6 (Tc: 127° C.).

FIG. 1 is a graph showing the TCC properties of ceramic/polymer composites obtained in Comparative Examples 1 and 2. As such, to increase the dielectric constant of the composite, processes of increasing the amount of ceramic filler, of changing the kind of ceramic filler, or of increasing the dielectric constant of epoxy may be used. In the TCC properties of two composites having different dielectric constants, manufactured by changing the amounts and kinds of ceramic filler, it can be seen that the TCC property does not fulfill X7R (−155−125° C., ΔC≦±15%) in the case where the dielectric constant increases by twice or more.

FIG. 2 shows the TCC properties of epoxy resins in Comparative Examples 3 and 4. As shown in FIG. 2, the epoxy resin of Comparative Example 3 has a low dielectric constant, and thus, is unsuitable for a decoupling capacitor. To solve such a problem, a metal organic catalyst is used, thus obtaining the epoxy resin (ΔC(%) DIM110_{—}5wtCo_{—}1) having an increased dielectric constant as in Comparative Example 4. However, the epoxy resin thus obtained has ΔC exceeding 30%, due to the high polarity of the epoxy resin even without the use of the filler. Therefore, it can be shown that such an epoxy resin is impossible to use for a decoupling capacitor.

FIG. 3 shows the TCC properties of PMMA (A), a bisphenol-A novolac epoxy resin (B), a brominated epoxy resin (C), and a resin mixture (D) of bisphenol-A epoxy resin, brominated epoxy resin and bisphenol-A epoxy resin, varying with the extent of the polarity of the polymers, in Example 1 and Comparative Examples 5 to 7. As shown in FIG. 3, PMMA as a thermoplastic resin, which is expected to have the highest polarity due to a carbonyl group actually has the worst temperature stability at a high temperature. In addition, the bisphenol-A novolac epoxy resin having high polarity due to the high ratios of epoxy group and phenyl group, and the brominated epoxy resin having higher polarity than a general bisphenol-A epoxy resin due to combination with bromine having high electronegativity, in that order, are confirmed to have better TCC properties. Further, the resin mixture of the composition D, containing a predetermined amount of bisphenol-A epoxy resin having the lowest polarity, appears to have an excellent TCC property.

FIG. 4 shows the TCC properties of the epoxy resin of the composition B and the epoxy resin of the composition D, each of which is the same thermosetting resin but has different polarity, mixed with the same filler in Example 2 and Comparative Example 8, to compare the differences when each polymer having different polarity is mixed with the same filler. As the above filler, ferroelectric powder having a high dielectric constant of 45 to 50 at room temperature and 1 kHz, which is to be added in an amount of 45 vol % to the polymer, is used. As the results, although the dielectric constants are the same within the error range at room temperature, the temperature stability of the composition D having low polarity is superior to that of the composition B as the temperature increases. This is believed to be because the use of the polymer having low polarity alleviates the reduction of temperature stability at a high temperature caused by using a large amount of a ferroelectric filler.

FIG. 5 shows the TCC properties varying with Tc of the ferroelectric materials in Comparative Examples 3 to 5. As is apparent from the drawing, the materials having the same dielectric constant (k=29) exhibit TCC properties varying with Tc. That is, the higher the Tc, the more stable the TCC property.

FIG. 6 shows the TCC properties of the ceramic/polymer composites obtained in Example 2 and Comparative Example 9, in which the ferroelectric powder that has been previously heat treated and pulverized to increase the dielectric constant of the filler is further heat treated and pulverized to obtain another filler having different Tc, which is then applied to manufacture a ceramic/polymer composite for embedded capacitors. The composite thus manufactured has a dielectric constant of about 50, which is the same as a system using the powder additionally treated as mentioned above and also is twice or more as high as a conventional ceramic/polymer composite for embedded capacitors, provided that the same filler is used in the same volume ratio. As shown in FIG. 6, the TCC property of the composite having low Tc (Comparative Example 9) falls out of X7R, and the change of capacitance exceeds 30%. However, it can be seen that the TCC property of the composite having high Tc (Example 2) of the present invention fulfills X7R.

As described hereinbefore, the present invention provides a resin composition and ceramic/polymer composite for embedded capacitors. In the present invention, the polymer having low polarity, high Ts and Tg, or high crosslinking density, and the ferroelectric filler having different Tc, are used, thereby alleviating the problems of temperature stability being deteriorated by the ceramic material having a high dielectric constant and obtaining the polymer-ceramic material having a high dielectric constant and excellent temperature stability. Further, the ceramic/polymer composite is applied to embedded capacitors, thus realizing high and stable capacitance.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A resin composition for embedded capacitors, comprising:
5-30 wt % of at least one resin selected from the group consisting of bisphenol-A epoxy resins and bisphenol-F epoxy resins;
60-85 wt % of at least one resin selected from the group consisting of novolac-type epoxy resins, polyimides and cyanate esters; and
10-30 wt % of a multi-functional epoxy resin.

2. A ceramic/polymer composite for embedded capacitors, comprising:
50-70 vol % of a resin composition, which comprises 5-30 wt % of at least one resin selected from the group consisting of bisphenol-A epoxy resins and bisphenol-F epoxy resins, 60-85 wt % of at least one resin selected from the group consisting of novolac-type epoxy resins, polyimides and cyanate esters, and 10-30 wt % of a multi-functional epoxy resin; and
30-50 vol % of a ceramic filler.

3. The ceramic/polymer composite as set forth in claim 2, wherein the ceramic filler is selected from the group consisting of BaTiO₃, PbTiO₃, PMT-PT, SrTiO₃, CaTiO₃, and MgTiO₃.

4. The ceramic/polymer composite as set forth in claim 2, wherein the ceramic filler has a dielectric constant increased by mixing ferroelectric powder with an additive to obtain a mixture, heat treating the mixture at 800 to 1300° C. for 0.5 to 2 hr, and pulverizing the heat treated mixture to a size of 0.01 to 10 μm.

5. The ceramic/polymer composite as set forth in claim 4, wherein the ceramic filler has a dielectric constant of 40 or more at room temperature in a range of 1 kHz.

6. The ceramic/polymer composite as set forth in claim 4, wherein the ceramic filler has a curie temperature (Tc) increased to 125° C. or more.

7. The ceramic/polymer composite as set forth in claim 4, further comprising a curing agent, a curing accelerator, a defoaming agent and/or a dispersing agent.

8. A dielectric layer of a capacitor, formed of the ceramic/polymer composite for embedded capacitors of claim 7.

9. A printed circuit board, comprising the dielectric layer of a capacitor of claim 8.

10. A method of increasing a dielectric constant of a ceramic filler for embedded capacitors, comprising:
heat treating ferroelectric powder at 800 to 1300° C. for 0.5 to 2 hr; and
pulverizing the heat treated powder to a size of 0.01 to 10 μm, to increase a curie temperature of the ceramic filler.

11. The method as set forth in claim 10, wherein the ferroelectric powder is selected from the group consisting of BaTiO₃, PbTiO₃, PMT-PT, SrTiO₃, CaTiO₃, and MgTiO₃.

12. The method as set forth in claim 10, wherein the heat treating of the ferroelectric powder is performed after mixing the ferroelectric powder with an additive selected from the group consisting of 2⁺, 3⁺ and 5⁺ oxides of Mn, Mg, Sr, Ca, Y and Nb, oxides of lanthanide elements including Ce, Dy, Ho, Yb and Nd, and combinations thereof.

13. The method as set forth in claim 10, wherein the ceramic filler has a dielectric constant of 40 or more at room temperature in a range of 1 kHz.

14. The method as set forth in claim 10, wherein the ceramic filler has a curie temperature increased by at least 2° C. after the heat treating and the pulverizing than before the heat treating and the pulverizing.

15. The method as set forth in claim 14, wherein the ceramic filler has a curie temperature of 125° C. or more.
